(19) United States
(12) Patent Application Publication
(10) Pub. No.: US 2004/0251550 A1
(43) Pub. Date: Dec. 16, 2004

(54) Semiconductor device and method of manufacturing the same

(76) Inventors: Takashi Yoda, Machida-shi (JP); Seiichi Omoto, Yokohama-shi (JP); Hisashi Kaneko, Fujisawa-shi (JP); Hirokazu Ezawa, Tokyo (JP)

Correspondence Address: Finnegan, Henderson, Farabow,, Garrett & Dunner, L.L.P., 1300 I Street, N.W., Washington, DC, 20005-3315, US

(21) Appl. No.: 10/663,799

(22) Filed: Sep. 17, 2003

(30) Foreign Application Priority Data
Jun. 10, 2003 (JP) 2003-165147

(51) Int. Cl. H01L 23/48

(52) U.S. Cl. 257/758

(57) ABSTRACT

Disclosed is a semiconductor device comprising a porous film formed above a semiconductor substrate, the porous film having at least one burying concave selected from the group consisting of a trench and a hole, a conductive barrier layer formed on the inner surface of the burying concave, a conductive member buried in the burying concave with the conductive barrier layer interposed between the porous film and the conductive member, and a mixed layer formed between the porous film and the conductive barrier layer, and containing a component of the porous film and a component of the conductive barrier layer.

### CROSS-REFERENCE TO RELATED APPLICATIONS

This application is based upon and claims the benefit of priority from the prior Japanese Patent Application No. 2003-165147, filed Jun. 10, 2003, the entire contents of which are incorporated herein by reference.

### BACKGROUND OF THE INVENTION

1. Field of the Invention

The present invention relates to a semiconductor device and a method of manufacturing the same.

2. Description of the Related Art

In recent years, a wiring structure of a multi-layered structure has come to be employed widely in the semiconductor device in place of a wiring structure of a single layer structure employed in the past in accordance with progress in miniaturization and increased operating speed of the semiconductor device. However the miniaturization, the high operating speed, and the employment of the multi-layered wiring structure in the semiconductor device bring about increases in the capacitance between the adjacent wiring layers and in the wiring resistance so as to give rise to the problem that the signal transmission is delayed. The delay in the signal transmission is denoted by the product of the capacitance (C) between the adjacent wiring layers and the resistance (R) of the wiring, i.e., the time constant CR.

Various measures have been taken in the past in an attempt to avoid the delay in signal transmission. For example, it has been studied to use copper wiring having a low resistance in place of the aluminum wiring for decreasing the resistance of the wiring. However, it is very difficult to work the copper film finely by the conventional dry etching process. Such being the situation, a damascene process described in the following is employed in general in the case of forming copper wiring. Specifically, a trench having a width equal to that of a wiring is formed first in an interlayer insulating film formed on a semiconductor substrate, followed by forming a copper film on the interlayer insulating film including the trench. Then, the excess copper film is removed from the surface of the interlayer insulating film by a chemical mechanical polishing (CMP) process to form a buried copper wiring.

On the other hand, as a measure for lowering the capacitance between the adjacent wiring layers, it has been studied to use a porous film having a low dielectric constant, e.g., a relative dielectric constant not higher than 2.5, as the interlayer insulating film in place of a silicon oxide film formed by a CVD method.

Where buried copper wiring is formed in the porous film noted above, a thin conductive barrier layer is formed in advance on the inner surface in the trench formed in the porous film in order to prevent the diffusion of copper used as the wiring material, followed by burying copper wiring within the trench covered with the conductive barrier layer. For example, Japanese Patent Disclosure (Kokai) No. 2002-110789 teaches the process of forming buried copper wiring wrapped in a barrier layer, comprising the steps of forming a wiring trench in a porous film (an insulating film having a low dielectric constant) such as a film of hydrogen silsesquioxane, forming a conductive barrier layer such as a Ta layer or a TaN layer within the wiring trench by a known method, e.g., a sputtering method, forming a copper film on the porous film including the wiring trench having the barrier layer formed therein, and removing the undesired portion of the copper film positioned outside the wiring trench and the barrier layer by a CMP method to form buried copper wiring wrapped in the barrier layer.

However, if the aspect ratio of the wiring trench, i.e., the ratio of the depth of the wiring trench to the width in the open portion of the wiring trench, is increased in the case of forming the conductive barrier layer by the sputtering method, the open portion of the wiring trench is closed by the barrier material so as to make it difficult to form a conductive barrier layer having a desired thickness on the inner surface of the wiring trench. Also, it is difficult to form the conductive barrier layer on the inner surface of the wiring trench with a sufficiently high bonding strength.

### BRIEF SUMMARY OF THE INVENTION

According to a first aspect of the present invention, there is provided a semiconductor device comprising:

a porous film formed above a semiconductor substrate, the porous film having at least one burying concave selected from the group consisting of a trench and a hole;

a conductive barrier layer formed on the inner surface of the burying concave;

a conductive member buried in the burying concave with the conductive barrier layer interposed between the porous film and the conductive member; and

a mixed layer formed between the porous film and the conductive barrier layer, and containing a component of the porous film and a component of the conductive barrier layer.

According to a second aspect of the present invention, there is provided a method of manufacturing a semiconductor device, comprising:

forming at least two conductive barrier layers having substantially the same component composition by a thermal CVD method on the inner surface of at least one burying concave selected from the group consisting of a trench and a hole formed in a porous film formed above a semiconductor substrate; and

burying a conductive member in the burying concave having the conductive barrier layers formed therein;

wherein the pressure for the thermal CVD process for forming the first conductive barrier layer is set lower than the pressure for the thermal CVD process for forming the other conductive barrier layer including the second conductive barrier layer.

Further, according to a third aspect of the present invention, there is provided a method of manufacturing a semiconductor device, comprising:

forming a first conductive barrier layer by a plasma CVD process on the inner surface of at least one burying concave selected from the group consisting of a trench and a hole formed in a porous film formed above a semiconductor substrate;

forming at least one second conductive barrier layer by a thermal CVD process or an atomic layer deposition on the inner surface of the burying concave having the first conductive barrier layer formed therein; and

burying a conductive member in the burying concave having the second conductive barrier layer formed therein.

### BRIEF DESCRIPTION OF THE SEVERAL VIEWS OF THE DRAWING

FIG. 1 is a cross-sectional view showing the construction of a semiconductor device according to a first embodiment of the present invention;

FIGS. 2A to 2F are cross-sectional views collectively showing the manufacturing process of a semiconductor device according to a second embodiment of the present invention;

FIGS. 3A and 3B are cross-sectional views collectively showing the state of the porous film in the vicinity of the wiring trench in the step of forming a conductive barrier layer by a thermal CVD method under the supply rate-determining condition according to the second embodiment of the present invention;

FIG. 4 is a graph showing the EDX-depth profile of the porous film in the vicinity of the wiring trench in Example 1 of the present invention;

FIG. 5 is a graph showing the relationship between the voltage applied to the second wiring layer and the leak current between the adjacent wiring layers in the semiconductor chip obtained in Example 1 of the present invention; and

FIG. 6 is a graph showing the relationship between the voltage applied to the second wiring layer and the leak current between the adjacent wiring layers in the semiconductor chip obtained in Comparative Example 1.

### DETAILED DESCRIPTION OF THE INVENTION

Some embodiments of the present invention will now be described in detail with reference to the accompanying drawings.

### FIRST EMBODIMENT

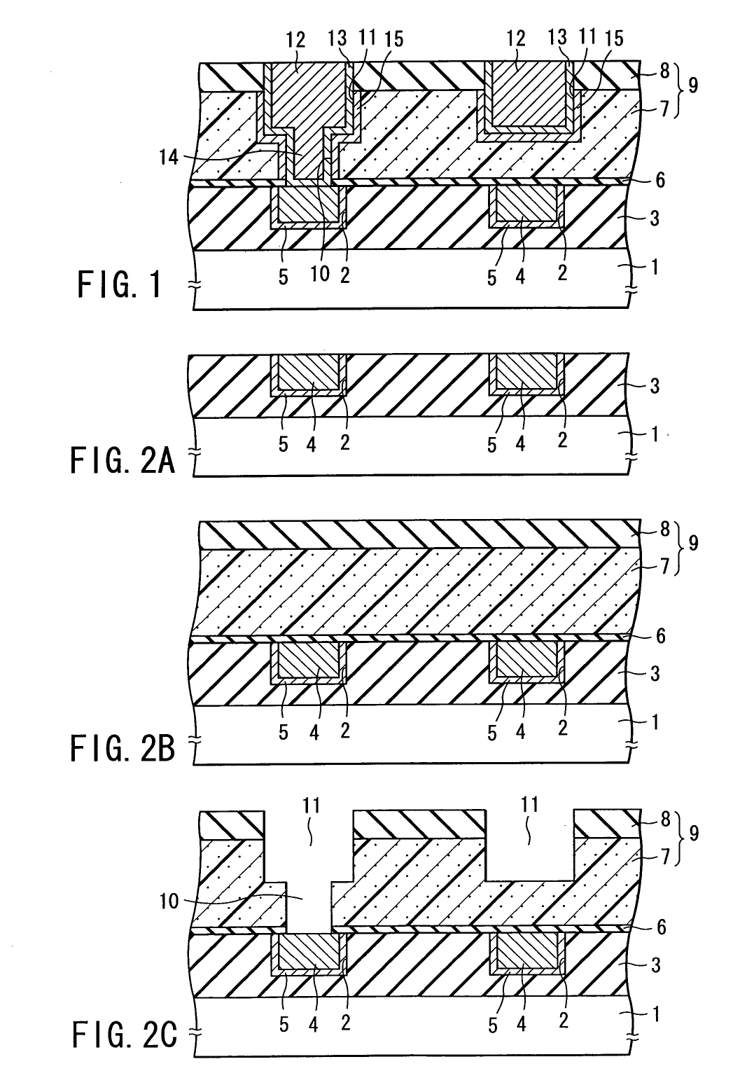

FIG. 1 is a cross-sectional view showing the construction of a semiconductor device having a multi-layered wiring structure according to a first embodiment of the present invention.

As shown in the drawing, a first interlayer insulating film 3 including a plurality of wiring trenches 2 constituting the burying concaves is formed on a semiconductor substrate (semiconductor wafer) 1 having active elements (not shown) formed therein. A first layer wiring 4 is buried in the wiring trench 2 formed in the first interlayer insulating film 3 with a conductive barrier layer 5 interposed between the first layer wiring 4 and the surface of the wiring trench 2. Incidentally, it is possible for some of the first layer wirings 4 to be electrically connected to the active element formed in the semiconductor substrate 1 through a via fill (not shown).

It is possible for the first interlayer insulating film 3 to be formed of a nonporous film such as a silicon oxide film, a boron phosphorus-added glass film (BPSG film), a phosphorus-added glass film (PSG film), a SiOF film, an organic spin-on glass or a polyimide film.

The first layer wiring 4 and the via fill are formed of, for example, copper, aluminum, tungsten or an alloy containing these metals.

The conductive barrier layer 5 is formed of, for example, TiSiN, TaN, WN, WSiN or TaAlN. It is acceptable for the conductive barrier layer 5 to be of a single layer structure or a laminate structure.

A diffusion preventing film 6 is formed on the first interlayer insulating film 3 having the first layer wiring 4 buried therein so as to prevent the diffusion of the metal constituting the first layer wiring 4. A laminate structure consisting of a porous film 7 and an insulating protective film 8 is formed on the diffusion preventing film 6 such that the porous film is in direct contact with the diffusion preventing film 6. It should be noted that the laminate structure consisting of the porous film 7 and the insulating protective film 8 constitutes a second interlayer insulating film 9. A via hole 10, which is a burying concave extending through the diffusion preventing film 6 to reach the first layer wiring 4, is formed to be open in the second interlayer insulating film 9. Wiring trenches 11 constituting the burying concaves are formed in that portion of the second interlayer insulating film 9 in which the via hole 10 is positioned and in the other portion of the second interlayer insulating film 9. Second layer wirings 12 are buried in the wiring trenches 11 with a conductive barrier layer 13 interposed between the second layer wiring 12 and the inner surface of the wiring trench 11. Incidentally, the bottom portion of some of the second layer wirings 12, e.g., the wiring 12 on the left side in the drawing, is electrically connected to the first layer wiring 4 through a via fill 14 formed by burying a conductive material in the via hole 10. Further, a mixed layer 15 is formed at the interface between the porous film 7 and the conductive barrier layer 13. The mixed layer 15 is contained the component of the porous film 7 and the component of the conductive barrier layer 13. It should be noted that the mixed layer 15 comprises a layer constituted with the porous layer 7, and the component of the conductive barrier layer 13 existing open cells of the layer.

The diffusion preventing film 6 referred to above is formed of, for example, SiN, SiC, or SiCN.

The porous film 7 referred to above includes open cells and has a low dielectric constant, e.g., a relative dielectric constant not higher than 2.5. The porous film 7 meeting the particular requirements is formed of, for example, a porous methyl silosesquioxane film (porous MSQ film), a porous polyarylene ether film (porous PAE film), or a porous hydrogen silosesquioxane film (porous HSQ) film. The particular porous film is formed by, for example, a coating method.

The insulating protective film 8 referred to above is formed of, for example, an organic silosesquioxane film or an inorganic silosesquioxane film.

The wiring trench 11 has an aspect ratio (D/W), i.e., the ratio of the depth (D) to the width (W), of 1.5 or more, for example of 1.5 to 2.

The second layer wiring 12 and the via fill 14 are formed of, for example, copper, aluminum, tungsten or an alloy containing these metals.

The conductive barrier layer 13 is formed of, for example, TiSiN, TaN, WN, WSiN or TaAlN. It is acceptable for the conductive barrier layer 13 to be of a single layer structure or a laminate structure.

As described above, the mixed layer 15 contains the component of the porous layer 7 and the component of the conductive barrier layer 13. It is desirable for the concentration of the component of the barrier layer 13 to be high on the side of the conductive barrier layer 13 and to be gradually lowered with increase in the distance from the conductive barrier layer 13. It is also desirable that the open cells of the porous layer 7 on the side of the conductive barrier layer 13 are substantially closed by the component of the conductive barrier layer 13.

It is desirable for the mixed layer 15 to have a thickness not larger than 30 nm, more desirably, to have a thickness falling within a range of between 2 nm and 20 nm. If the thickness of the mixed layer 15 exceeds 30 nm, it is possible for the current leakage to take place between the adjacent second layer wirings 12 formed in the second interlayer insulating film 9 including the porous film 7.

As described above, according to the first embodiment of the present invention, the conductive barrier layers 13 are formed on the inner surfaces of the wiring trench 11 and the via hole 10 formed in the second interlayer insulating film 9. Also, the second layer wiring 12 is formed in the wiring trench 11 in contact with the conductive barrier layer 13. The via fill 14 is formed in the via hole 10 in contact with. the conductive barrier layer 13. Further, the mixed layer 15 containing the component of the porous film 7 and the component of the conductive barrier layer 13 is formed at the interface between the porous film 7 included in the second interlayer insulating film 9 and the conductive barrier layer 13. The particular construction permits improving the bonding strength of the conductive barrier layer 13 to the inner surfaces of the wiring trench 11 and the via hole 10.

Particularly, the bonding strength of the conductive barrier layer 13 to the inner surfaces of the wiring trench 11 and the via hole 10 can be further improved in the case where the mixed layer 15 is constructed such that the concentration of the component of the conductive barrier layer 13 is set high on the side of the barrier layer 13 and is gradually lowered with increase in the distance from the barrier layer 13, and that the open cell of the porous film 7 is substantially closed by the component of the conductive barrier layer 13 on the side of at least the conductive barrier layer 13. As a result, it is possible to provide a semiconductor device having a buried wiring structure of a high reliability.

Also, in the case where the mixed layer 15 has a thickness not larger than 30 nm, it is possible to prevent the current leakage between the adjacent second layer wirings 12 formed in the second interlayer insulating film 9 including the porous film 7.

To be more specific, the mixed layer 15 is effective for improving the bonding strength of the conductive barrier layer 13 to the inner surfaces of the wiring trench 11 and the via hole 10, as described above. It should also be noted that the mixed layer 15 contains the component of the conductive barrier layer 13. Therefore, if the thickness of the mixed layer 15, particularly, the thickness in the planar direction of the porous film 7, is increased, the current tends to leak from the second layer wiring 12 formed in the second interlayer insulating film 9 including the porous film 7 into the adjacent second layer wiring 12 through the mixed layer 15.

Under the circumstances, it is possible to suppress or prevent the current leakage between the adjacent second layer wirings 12 formed in the second interlayer insulating film 9 by limiting the thickness of the mixed layer 15 to a level not higher than 30 nm, i.e., by limiting the thickness of the mixed layer 15 to a level at which the mixed layer 15 does not perform the function of the passageway of the leaking current between the adjacent second layer wirings 12 formed in the second interlayer insulating film 9 including the porous film 7.

Particularly, the current leakage between the adjacent second layer wirings 12 can be prevented more effectively by limiting the thickness of the mixed layer 15 to a level not higher than 30 nm and by controlling the distribution of the concentration in respect of the component of the conductive barrier layer 13 contained in the mixed layer 15 such that the concentration noted above is high on the side of the conductive barrier layer 13 and is gradually lowered with increase in the distance from the conductive barrier layer 13.

As described above, in the first embodiment of the present invention, it is possible to form the second layer wirings 12 having a high bonding strength in the second interlayer insulating film 9 including the porous film 7 having a low dielectric constant and to prevent the current leakage between the adjacent second layer wirings 12 so as to make it possible to provide a semiconductor device having a stable performance with a high reliability.

### SECOND EMBODIMENT

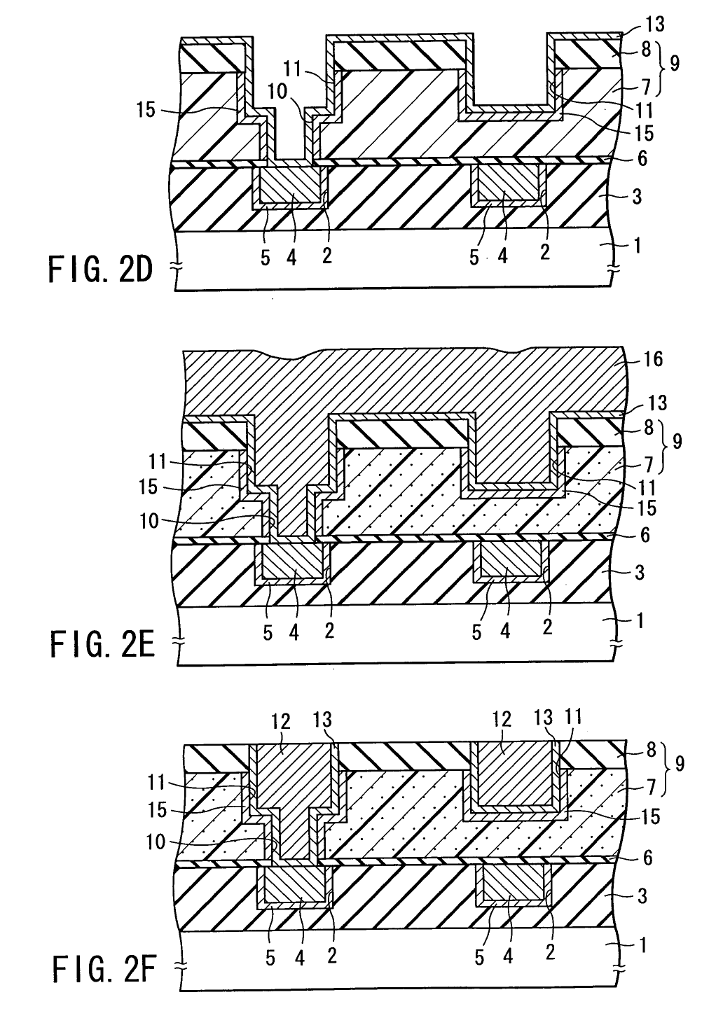

The manufacturing method of the semiconductor device according to the first embodiment of the present invention described above will now be described as a second embodiment of the present invention with reference to FIGS. 2A to 2F.

(First Step)

In the first step, the first interlayer insulating film 3 is formed on a semiconductor substrate (semiconductor wafer) 1 having active elements (not shown) formed therein in advance. Then, a pattern, e.g., a resist pattern, is formed on the first interlayer insulating film 3, followed by selectively removing the first interlayer insulating film 3 by a reactive ion etching (RIE) with the resist pattern used as a mask so as to form via holes (not shown) extending to reach the surface of the semiconductor substrate 1. After formation of the via holes, wiring trenches 2 are formed in that portion of the first interlayer insulating film 3 at which a prescribed via hole is positioned and in the other portion of the first interlayer insulating film 3 by RIE using another mask pattern. Further, the conductive barrier layer 5 is formed by, for example, a sputtering method on the first interlayer insulating film 3 including the via holes and the wiring trenches 2, followed by forming a film of the wiring material on the conductive barrier layer 5.

In the next step, the excess wiring material film and the conductive barrier layer 5 positioned on the first interlayer insulating film 3 excluding the via holes and the wiring trenches 2 are removed by a chemical mechanical polishing (CMP) treatment so as to form in the first interlayer insulating film 3 the first layer wiring 4 wrapped in the conductive barrier layer 5 and the first layer wiring (not shown) wrapped in the conductive barrier layer 5 and electrically connected through a via fill (not shown) to the active element formed in the semiconductor substrate 1. The CMP treatment includes a first CMP treatment for removing, for example, the excess wiring material film positioned on the first interlayer insulating film 3 and a second CMP treatment for removing the excess conductive barrier layer 5 positioned on the first interlayer insulating film 3.

The first interlayer insulating film 3 and the conductive barrier layer 5 can be formed by using the materials and the methods equal to those described previously in conjunction with the first embodiment of the present invention.

It is possible to use, for example, copper, aluminum, tungsten or an alloy containing these metals as the wiring material.

The wiring material film can be formed by forming a seed layer on the entire surface by, for example, a sputtering method, followed by employing a plating method with the seed layer used as a common electrode.

(Second Step)

As shown in FIG. 2B, a diffusion preventing film 6 is formed on the first interlayer insulating film 3 having the first layer wirings 4 buried therein. Then, the porous film 7 is formed by, for example, a coating method on the diffusion preventing film 6, followed by forming the insulating protective film 8 on the porous film 7 so as to form the second interlayer insulating film 9 consisting of the porous film 7 and the insulating protective film 8.

The diffusion preventing film 6, the porous film 7 and the insulating protective film 8 can be formed by using the materials equal to those described previously in conjunction with the first embodiment of the present invention.

Each of the diffusion preventing film 6 and the insulating protective film 8 can be formed by, for example, a CVD method.

The insulating protective film 8 plays the role of protecting the porous film 7 positioned below the insulating protective film 8 in the dry etching process for removing the mask formed of a resist pattern described herein later and in the chemical mechanical polishing (CMP) treatment for removing the excess wiring material described herein later.

(Third Step)

A pattern such as a resist pattern is formed on the second interlayer insulating film 9 of a laminate structure consisting of the porous film 7 and the insulating protective film 8, followed by selectively removing the second interlayer insulating film 9 by RIE using the resist pattern as a mask so as to form the via hole 10, which is the burying concave extending to reach the diffusion preventing film 6, as shown in FIG. 2C. Then, the wiring trenches 11 are formed in that portion of the second interlayer insulating film 9 at which the via hole 10 is positioned and in the other portion of the second interlayer insulating film 9 by RIE using another mask pattern, followed by removing the exposed portion of the diffusion preventing film 6 by RIE.

(Fourth Step)

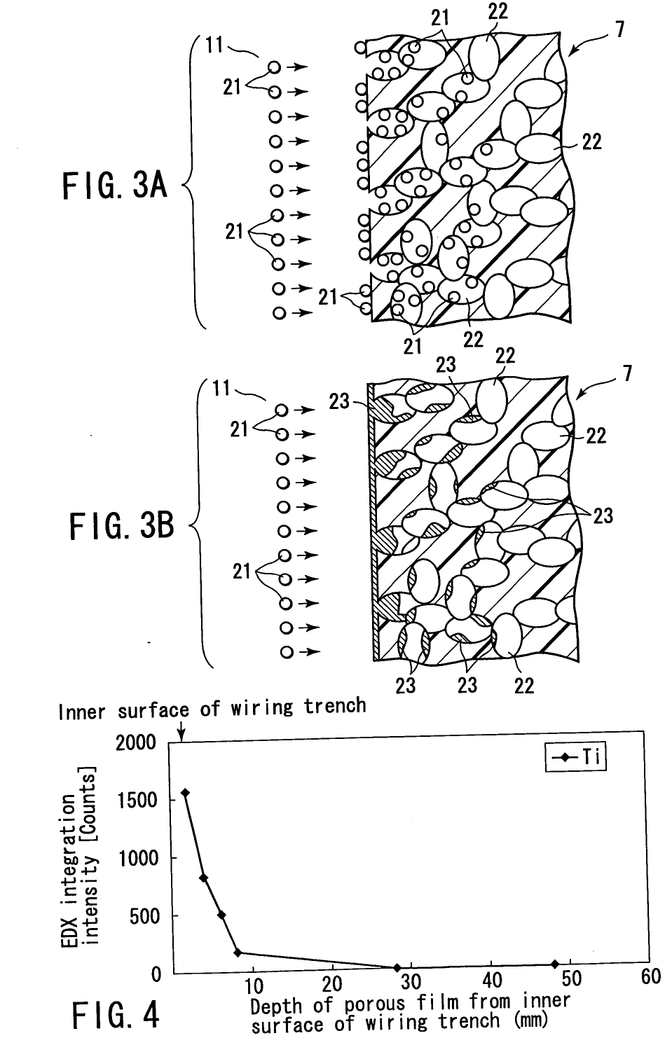

At least two conductive barrier layers, e.g., two conductive barrier layers, are formed by a thermal CVD method using prescribed raw material gases on the second interlayer insulating film 9 including the via hole 10 and the wiring trenches 11. In this step, the thermal CVD process for forming the first conductive barrier layer is carried out under the pressure lower than that for the thermal CVD process for forming the second conductive barrier layer. In other words, the first conductive barrier layer is formed under the supply rate-determining conditions. In the thermal CVD process under the particular conditions, a raw material gas 21 permeates from, for example, the wiring trench 11 into open cells 22 formed in the porous film 7, as shown in FIG. 3A. It should be noted that a film is formed under the supply rate-determining conditions in this step. Therefore, the raw material gas 21 is decomposed in that portion of the open cell 22 which is exposed to the inner surface of the wiring trench 11 in a very short time from the initiation of the film formation so as to bring about accumulation of a barrier material 23, with the result that the opening of the open cell 22 exposed to the inner surface of the wring trench 11 is closed by the barrier material 23, as shown in FIG. 3B. It follows that the raw material gas 21 is prevented from permeating deep into the open cell 22, i.e., permeating to reach a position reasonably apart from the wiring trench 11. As a result, the region in which the barrier material 23 is accumulated from the wiring trench 11 toward the inner region of the open cell 22 formed in the porous film 7, e.g., toward the inner region in a direction parallel to the surface of the porous film 7, is limited to a thickness not larger than, for example, 30 nm as measured from the inner surface of the wiring trench 11. It follows that the mixed layer 15 containing the component of the porous film 7 and the component of the conductive barrier layer and having a controlled thickness is formed on the porous film 7 in the vicinity of the inner surfaces of the wiring trench 11 and the via hole 10, as shown in FIG. 2D. Because of the accumulating behavior of the conductive barrier layer shown in FIGS. 3A and 3B, the mixed layer 15 is formed such that the concentration of the component of the barrier layer is high in the vicinity of the inner surfaces of the wiring trench 11 and the via hole 10 and is gradually lowered with increase in the distance from the inner surfaces of the wiring trench 11 and the via hole 10, and that the open cells of the porous film 7 positioned on the inner surfaces noted above are substantially closed by the component of the conductive barrier layer. Then, a thermal CVD process under a high pressure, i.e., a thermal CVD process under the reaction rate-determining conditions which are satisfied the step coverage, is carried out without exposing the semiconductor substrate 1 to the air atmosphere so as to form the conductive barrier layer 13 on the second interlayer insulating film 9 including the wiring trench 11 and the via hole 10 having the mixed layer 15 formed in the vicinity of the inner surfaces thereof as shown in FIG. 2D.

Various raw material gases can be used in the thermal CVD process in accordance with the kind of the conductive barrier layer to be formed. For example, in the case of forming a conductive barrier layer consisting of TiSiN, used is a mixed gas containing at least one a titanium compound gas selected from the group consisting of tetrakis(dimethylamino)titanium (TDMAT), tetrakis(diethylamino)titanium (TDEAT), and TiCl₄, at least one a silicon compound gas selected from the group consisting of SiH₄ and Si₂H₆, and at least one nitrogen-containing gas selected from the group consisting of NH₃ and N₂. In the case of forming a conductive barrier layer consisting of TaN, used is a mixed gas containing a tantalum compound gas selected from the group consisting of pentakis(dimethylamino)tantalum (PDMAT) and tertbutylimido tris-diethylamido tantalum (TBTDET), and at least one nitrogen-containing gas selected from the group consisting of NH₃ and N₂. In the case of forming a conductive barrier layer consisting of WN, used is a mixed gas containing a tungsten compound gas such as a WF₆ gas, and at least one nitrogen-containing gas selected from the group consisting of NH₃ and N₂. In the case of forming a conductive barrier layer consisting of WSiN, used is a mixed gas containing a tungsten compound gas such as a WF₆ gas, at least one a silicon compound gas selected from the group consisting of a SiH₄ gas and a Si₂H₆ gas, and at least one nitrogen-containing gas selected from the group consisting of an NH₃ gas and a N₂ gas. In the case of forming a conductive barrier layer consisting of TaAlN, used is a mixed gas containing a tantalum compound gas selected from the group consisting of PDMAT gas and TBTDET gas, at least one an aluminum compound gas selected from the group consisting of a trimethyl aluminum (TMA) gas and a dimethyl aluminum hydride gas, and at least one nitrogen-containing gas selected from the group consisting of an NH₃ gas and a N₂ gas. Also, in the thermal CVD process, it is acceptable to use a carrier gas such as an Ar gas, a He gas, or a N₂ gas together with the raw material gases noted above.

It is desirable for the thermal CVD process for forming the first conductive barrier layer to be carried out under the temperature of 300 to 370° C. and the pressure of 0.4 to 0.8 Torr. Also, it is desirable for the thermal CVD process for forming the other conductive barrier layers including the second conductive barrier layer to be carried out under the temperature of 300 to 370° C. and the pressured not lower than 1.0 Torr. If the thermal CVD process for forming the first conductive barrier layer is carried out under the pressure lower than 0.4 Torr, the forming rate of the barrier layer is lowered so as to lower the productivity of the semiconductor device. On the other hand, if the CVD process for forming the first conductive barrier layer is carried out under the pressure exceeding 0.8 Torr, it is difficult to form the barrier layer under the supply rate-determining conditions, with the result that it is difficult to limit the permeation of the component of the conductive barrier layer to a region in the vicinity of the interface between the porous film and the conductive barrier layer. Further, if the thermal CVD process for forming, for example, the second conductive barrier layer is carried out under the pressure lower than 1.0 Torr, it is difficult to form a conductive barrier layer satisfactory in the step coverage on the inner surface of the burying concave having a high aspect ratio.

(Fifth Step)

A wiring material film 16 is formed on the conductive barrier layer 13 formed on the second interlayer insulating film 9 including the wiring trench 11 and the via hole 10, as shown in FIG. 2E.

In the next step, the excess wiring material film 16 and the conductive barrier layer 13, which are positioned on the second interlayer insulating film 9 excluding the via hole 10 and the wiring trench 11, are removed by a CMP treatment so as to form in the second interlayer insulating film 9 the second layer wiring 12 wrapped in the conductive barrier layer 13 and the second wiring layer 12 wrapped in the conductive barrier layer 13 and connected to the first layer wiring 4 through the via fill 14, thereby manufacturing a semiconductor device as shown in FIG. 2F.

It is possible to use, for example, copper, aluminum, tungsten or an alloy containing these metals as the wiring material noted above.

The wiring material film can be formed by forming a seed layer on the entire surface by, for example, a sputtering method, followed by employing a plating method with the seed layer used as a common electrode.

The CMP treatment includes a first CMP treatment for removing, for example, the excess wiring material film positioned on the second interlayer insulating film 9 and a second CMP treatment for removing the excess conductive barrier layer 13 positioned on the second interlayer insulating film 9.

As described above, according to the second embodiment of the present invention, the via hole 10 and the wiring trench 11, which constitute the burying concaves, are formed in the second interlayer insulating film 9. When at least two conductive barrier layers having substantially the same composition are formed by the thermal CVD process on the inner surfaces of the via hole 10 and the wiring trench 11, the thermal CVD process for forming the first conductive barrier layer is carried out under the pressure lower than the pressure for the thermal CVD process for forming the other conductive barrier layers including the second conductive barrier layer. In other words, the supply rate-determining conditions are established. As a result, it is possible to form the mixed layer 15 containing the component of the porous layer 7 and the component of the conductive barrier layer and having a controlled thickness on the porous film 7 in the vicinity of the inner surfaces of the wiring trench 11 and the via hole 10, as shown in FIG. 2D. Then, a thermal CVD process under a high pressure, i.e., a thermal CVD process under the reaction rate-determining conditions which are satisfied the step coverage, is carried out. As a result, it is possible to form the conductive barrier layer 13 with a high bonding strength on the second interlayer insulating film 9 including the inner surfaces of the wiring trench 11 and the via hole 10 with the mixed layer 15 interposed therebetween.

Particularly, it is desirable to carry out the thermal CVD process for forming the first conductive barrier layer under the temperature of 300 to 370° C. and the pressure of 0.4 to 0.8 Torr and to carry out the thermal CVD process for forming the other conductive barrier layers including the second conductive barrier layer under the temperature of 300 to 370° C. and the pressure not lower than 1.0 Torr. In this case, it is possible to form the mixed layer 15 having the thickness controlled to a level not higher than, for example, 30 nm on the porous film 7 in the vicinity of the inner surfaces of the wiring trench 11 and the via hole 10. It is also possible to form the conductive barrier layer 13 having a high bonding strength and a relatively uniform thickness on the second interlayer insulating film 9 including the inner surfaces of the wiring trench 11 and the via hole 10 with the mixed layer 15 interposed therebetween.

After formation of the conductive barrier layer, 13, the wiring material film 16 is formed on the second interlayer insulating film 9 including the wiring trench 11 and the via hole 10, followed by removing the excess wiring material film 16 and the excess conductive barrier layer 13 on the second interlayer insulating film 9 by the CMP treatment. As a result, it is possible to form the second layer wiring 12 and the via fill 14, each wrapped in the conductive barrier layer 13 having a high bonding strength, in the wiring trench 11 and the via hole 10.

It should also be noted that, since the mixed layer 15 having a controlled thickness can be formed on the porous film 7 in the vicinity of the inner surfaces of the wiring trench 11 and the via hole 10, it is possible to prevent the current leakage between the adjacent second layer wirings 12 by forming the second layer wirings 12 in the second interlayer insulating film 9 including the porous film 7, as described previously in conjunction with the first embodiment of the present invention.

As described above, the second layer wiring 12 can be formed with a high bonding strength within the second interlayer insulating film 9 including the porous film 7 having a low dielectric constant in the second embodiment of the present invention. In addition, the current leakage between the adjacent second layer wirings 12 can be prevented. It follows that the manufacturing method according to the second embodiment of the present invention makes it possible to manufacture a semiconductor device having a stable performance with a high reliability.

### THIRD EMBODIMENT

A third embodiment of the present invention relates to the manufacturing process (fourth step) of the semiconductor device according to the second embodiment of the present invention described above. Specifically, in the third embodiment of the present invention, a plasma CVD process using a prescribed raw material gas is employed in place of the thermal CVD process under a low pressure in forming the first conductive barrier layer, followed by forming an additional conductive barrier layer on the first conductive barrier layer by employing a thermal CVD process so as to form the conductive barrier layer of a laminate structure.

A raw material gas similar to that for the thermal CVD process described previously in conjunction with the second embodiment of the present invention is used in the plasma CVD process employed in the third embodiment. In addition, a carrier gas such as an Ar gas, a He gas or a N₂ gas is used in the plasma CVD process together with the raw material gas.

Where the plasma CVD process is carried out by using, for example, a plasma CVD apparatus equipped with a vacuum container housing parallel plate electrodes, it is desirable to set the degree of vacuum within the vacuum container at 1 mTorr to 15 mTorr.

It is desirable to carry out the thermal CVD process under the temperature of 300 to 370° C. and the pressure not lower than 1.0 Torr. It is desirable for the plural conductive barrier layers formed by the plasma CVD process and the thermal CVD process to have substantially the same composition as in the second embodiment of the present invention described above, though it is acceptable for a slight difference in composition to be generated between the plural conductive barrier layers depending on the difference in the film-forming method.

As described above, in the third embodiment of the present invention, the first conductive barrier layer is formed by the plasma CVD process under the supply rate-determining conditions, with the result that it is possible to form the mixed layer 15 containing the component of the porous film 7 and the component of the conductive barrier layer and having a controlled thickness on the porous film 7 in the vicinity of the inner surfaces of the wiring trench 11 and the via hole 10, as in the second embodiment described above. It should also be noted that the mixed layer 15 is constructed in respect of the distribution of the component of the conductive barrier layer contained in the mixed layer 15 such that the concentration is high in the vicinity of the inner surfaces of the wiring trench 11 and the via hole 10 and is gradually lowered with increase in the distance from the inner surfaces noted above, and that the open cells of the porous film 7 positioned on the inner surfaces noted above are substantially closed by the component of the conductive barrier layer.

As described above, according to the third embodiment of the present invention, it is possible to form the mixed layer 15 with a high bonding strength on the second interlayer insulating film 9 including the inner surfaces of the wiring trench 11 and the via hole 10 as in the second embodiment described above. In addition, it is possible to form a plurality of second layer wirings 12 in the second interlayer insulating film 9 including the porous film 7 such that the current leakage between the adjacent second layer wirings 12 can be prevented.

It follows that it is possible to manufacture a semiconductor device having the second layer wiring 12, which exhibits a stable performance with a high reliability, buried in the second interlayer insulating film 9 including the porous film 7 having a low dielectric constant.

Incidentally, in each of the first to third embodiments of the present invention described above, the semiconductor device comprises two insulating films in which the buried wirings are formed. Alternatively, it is also possible for the semiconductor device to comprise a multi-layered wiring structure in which the buried wirings are formed in three or more insulating films.

Also, in each of the first to third embodiments described above, the insulating film of a laminate structure including a porous film and an insulating protective film is used as the second insulating film in which the buried wirings are formed. However, the present invention is not limited to the particular construction. For example, it is possible to use the insulating film of the particular laminate structure as the first insulating film or as the other insulating films including the third insulating film. Also, the insulating film having the particular laminate structure is used as a single insulating film in which the buried wirings are formed. However, it is also possible to form a plurality of insulating films each having the particular laminate structure for forming the buried wirings therein.

Further, in each of the second and third embodiments of the present invention described above, a thermal CVD process is employed in forming the conductive barrier layer as the film-forming process following the film-forming process under the supply rate-determining conditions. However, it is also possible to employ an atomic layer deposition (ALD) process in place of the thermal CVD process noted above.

Some Examples of the present invention will now be described with reference to FIGS. 2A to 2F.

### EXAMPLE 1

In the first step, a first interlayer insulating film 3 consisting of a silicon oxide film having a thickness of 300 nm was formed on a semiconductor substrate (semiconductor wafer) 1 having active elements (not shown) formed therein, as shown in FIG. 2A. Then, a resist pattern was formed on the first interlayer insulating film 3, followed by selectively removing the first interlayer insulating film 3 by a reactive ion etching (RIE) with the resist pattern used as a mask so as to form via holes (not shown) extending to reach the surface of the semiconductor substrate 1. After formation of the via holes, wiring trenches 2 were formed by a RIE method using another mask pattern in that portion of the first interlayer insulating film 3 at which a prescribed via hole was positioned and in the other portion of the first interlayer insulating film 3. Then, a conductive barrier layer 5 consisting of TiSiN and having a thickness of 5 nm was formed by a CVD method on the first interlayer insulating film 3 including the via hole and the wiring trenches 2. After formation of the conductive barrier layer 5, a copper seed layer (not shown) was formed in a thickness of 100 nm by a sputtering method. Further, a copper plating treatment was applied with the copper seed layer used as a common electrode so as to form a copper film on the copper seed layer including the via hole and the wiring trenches 2.

In the next step, the excess copper film and the excess conductive barrier layer 5 positioned on the first interlayer insulating film 3 excluding the via hole and the wiring trenches 2 were removed by a chemical mechanical polishing (CMP) treatment so as to form in the first interlayer insulating film 3 a first layer wiring 4 wrapped in the conductive barrier layer 5 and another first layer wiring (not shown) wrapped in the conductive barrier layer 5 and connected to the active element formed in the semiconductor substrate 1 through a via fill (not shown). The CMP treatment included a CMP treatment for copper, which was employed for removing the excess copper film positioned on the first interlayer insulating film 3, and a CMP treatment for a barrier, which was employed for removing the excess conductive barrier layer 5 positioned on the first interlayer insulating film 3.

In the next step, a diffusion preventing film 6 consisting of SiC and having a thickness of 100 nm was formed by a CVD process on the first interlayer insulating film 3 having the first layer wiring 4 buried therein, as shown in FIG. 2B. Then, a porous PAE film (porous film) 7 having a thickness of 400 nm was formed by a coating method on the diffusion preventing film 6, followed by forming an insulating protective film 8 consisting of an organic siloxane compound and having a thickness of 200 nm on the porous PAE film 7 so as to form a second interlayer insulating film 9 of a laminate structure consisting of the porous PAE film 7 and the insulating protective film 8 and having a total thickness of 600 nm.

In the next step, a resist pattern was formed on the second interlayer insulating film 9 having a laminate structure consisting of the porous PAE film 7 and the insulating protective film 8, followed by selectively removing the second interlayer insulating film 9 by RIE using the resist pattern as a mask so as to form via holes 10 extending to reach the diffusion preventing film 6, as shown in FIG. 2C. Then, wiring trenches 11 each having a width of 150 nm and a depth of 300 nm were formed apart from each other by 150 nm by RIE using another mask pattern in that portion of the second interlayer insulating film 9 at which a prescribed via hole 10 was positioned and in the other portion of the second interlayer insulating film 9. Further, that portion of the diffusion preventing film 6 which was exposed to the bottom portion of the via hole was removed by RIE. Each of these wiring trenches 11 had an aspect ratio (D/W), i.e., the ratio of the depth (D) to the width (W), of 2.

In the next step, the semiconductor substrate 1 was set within a vacuum container (not shown) having a heater arranged outside the vacuum container. Under this condition, each of TDMAT/SiH₄/N₂ gas mixture used as a raw material gas and an argon gas used as a carrier gas was introduced into the vacuum container, and the gas within the vacuum container was discharged so as to set a partial pressure of the raw material gas at 0.5 Torr, and the film-forming temperature was set at 330° C. In other words, the thermal CVD process was carried out under the supply rate-determining conditions. As a result, a first conductive barrier layer consisting essentially of TiSiN and having a thickness of 5 nm, i.e., the thickness on the insulating protective film 8, was formed on the second interlayer insulating film 9 including the via hole 10 and the wiring trench 11. After the CVD process, the EDX-depth profile analysis in the planar direction of the porous film 7 from the wiring trench 11 was applied to the porous film 7 in the vicinity of, for example, the wiring trench 11. FIG. 4 is a graph showing the result. As apparent from FIG. 4, titanium (Ti) was found to have been permeated into the porous film 7 by only a distance not larger than 30 nm from the inner surface of the wiring trench 11. In addition, the pores of the porous film 7 exposed to the wiring trench 11 were found to have been closed by TiSiN. In other words, the mixed layer 15 formed on the porous film 7 in the vicinity of the wiring trench 11 was formed of Ti, Si, N, C and O. Then, after formation of the first conductive barrier layer, the partial pressure of the raw material gas within the vacuum container was set at 1.0 Torr, and the film-forming temperature was set at 330° C. In other words, the thermal CVD process was carried out under the reaction rate-determining conditions. In this case, a second conductive barrier layer consisting essentially of TiSiN and having a thickness of 5 nm (i.e., a thickness as measured on the insulating protective film 8) was formed on the second interlayer insulating film 9 including the inner surfaces of the via hole 10 and the wiring trench 11. By this process, a conductive barrier layer 13 having a thickness of 5 to 10 nm and consisting essentially of TiSiN was formed on the second interlayer insulating film 9 including the wiring trench 11 and the via hole 10 and having the mixed layer 15, which had a thickness not larger than 30 nm, formed in the vicinity of the inner surface, as shown in FIG. 2D.

In the next step, a copper seed layer (not shown) having a thickness of 100 nm was formed after the thermal CVD process by a sputtering process on the conductive barrier layer 13 positioned on the second interlayer insulating film 9 including the wiring trench 11 and the via hole 10 without exposing the semiconductor substrate 1 to the air atmosphere. Further, a copper plating treatment was applied with the copper seed layer used as a common electrode so as to form a copper film 16 on the copper seed layer including the via hole 10 and the wiring trench 11, as shown in FIG. 2E.

After formation of the copper film 16, the excess copper film 16 and the excess conductive barrier layer 13 positioned on the second interlayer insulating film 9 excluding the via hole 10 and the wiring trench 11 were removed by a CMP treatment so as to form in the second interlayer insulating film 9 a second layer wiring 12 wrapped in the conductive barrier layer 13 and another second layer wiring 12 wrapped in the conductive barrier layer 13 and electrically connected to the first layer wiring 4 through the via fill 14, thereby manufacturing a plurality of semiconductor devices (semiconductor chips) each having the multi-layered wiring structure as shown in FIG. 2F on the semiconductor wafer. The CMP treatment included a CMP treatment for copper, which was employed for removing the excess copper film positioned on the second interlayer insulating film 9, and a CMP treatment for a barrier, which was employed for removing the excess conductive barrier layer 13 positioned on the second interlayer insulating film 9.

### COMPARATIVE EXAMPLE 1

A plurality of semiconductor devices (semiconductor chips) were manufactured on the semiconductor wafer by a method similar to that for Example 1, except that the conductive barrier layer was formed on the second interlayer insulating film including the porous film having the via hole and the wiring trench formed therein by only a thermal CVD process in which the partial pressure of the raw material gas was set at 1.0 Torr and the film-forming temperature was set at 330° C., i.e., by only the thermal CVD process under the reaction rate-determining conditions.

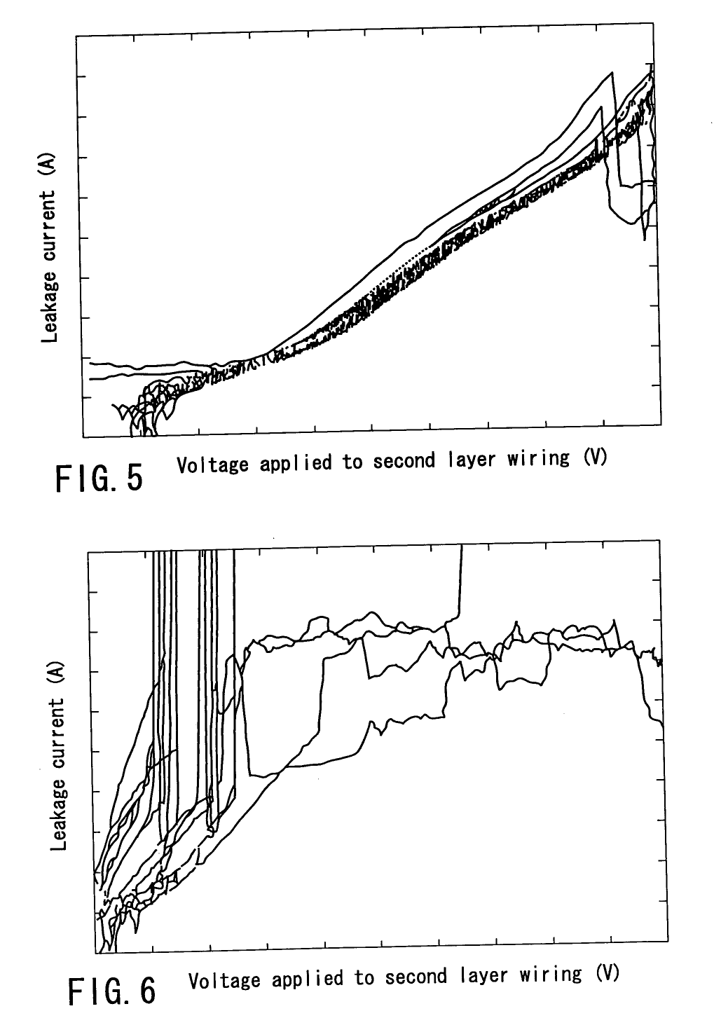

The leaking current between the wiring layers was measured while gradually elevating the voltage applied to the second layer wiring in respect of 20 semiconductor chips obtained for each of Example 1 and Comparative Example 1. FIGS. 5 and 6 show the results for Example 1 and Comparative Example 1, respectively.

As apparent from FIG. 5, the leaking current was increased moderately in accordance with increase in the voltage in respect of all of the 20 semiconductor chips for Example 1, supporting that it was possible to suppress or prevent the current leakage between the adjacent second layer wirings.

On the other hand, FIG. 6 shows that a large leaking current was generated in almost all the 20 semiconductor chips for Comparative Example 1 when a low voltage was supplied to the second layer wirings. The particular leaking current was generated by the behavior described in the following.

Specifically, in Comparative Example 1, the conductive barrier layer was formed on the second interlayer insulating film including the porous film having the via hole and the wiring trench formed therein by only a thermal CVD process in which the partial pressure of the raw material gas was set at 1.0 Torr and the film-forming temperature was set at 330° C., i.e., by only the thermal CVD process under the reaction rate-determining conditions. In the thermal CVD process under the reaction rate-determining conditions, the opening of the cell exposed to the inner surface of the wiring trench is not closed in a very short time after initiation of the film-forming operation by the barrier material formed by the decomposition of the raw material gas. Therefore, the raw material gas used for the thermal CVD process permeates deep into the porous film from the inner surface of the wiring trench in the thickness direction of the open cell formed in the porous film and in the planar direction of the porous film so as to be decomposed thermally into a barrier material. As a result, the barrier material thus formed remains inside the porous film. The residual depth of the barrier material thus formed, particularly, the residual depth in the planar direction of the porous film, far exceeds 30 nm. As a result, if the second layer wirings are formed in the second interlayer insulating film including the particular porous film, the current leakage is generated between the adjacent wirings under a low voltage applied to the second layer wirings because the barrier material remains in that portion of the porous film which is positioned between the adjacent second layer wirings.

### EXAMPLE 2

A plurality of semiconductor devices (semiconductor chips) were manufactured on the semiconductor wafer by a method similar to that for Example 1, except that a conductive barrier layer was formed by the method described in the following on the second interlayer insulating film including the porous film having the via hole and the wiring trench formed therein.

Specifically, the semiconductor substrate 1 was disposed on one of the parallel plate electrodes arranged within a vacuum container, i.e., disposed on the lower electrode connected to the ground. Each of a TDMAT/SiH₄/N₂ gas used as a raw material gas and an argon gas used as a carrier gas was supplied into the vacuum container. After the gas within the vacuum container was discharged so as to set the pressure within the vacuum container at 5 Torr, an electric power having an output of 1 kW was applied from a high frequency power source of 13.56 MHz to the upper electrode so as to generate a plasma between the parallel plate electrodes. By the plasma CVD process under the particular supply rate-determining conditions described above, a first conductive barrier layer consisting essentially of TiSiN and having a thickness of 5 nm was formed on the second interlayer insulating film including the via hole and the wiring trench. In this case, titanium (Ti) was allowed to permeate slightly into the porous film, the permeating distance being not longer than 30 nm, and the pore of the porous film exposed to the wiring trench was closed by TiSiN formed by decomposition of the raw material gases. Then, the semiconductor wafer was mounted within a vacuum container (not shown) having a heater arranged outside the vacuum container without exposing the semiconductor wafer to the air atmosphere. Then, each of a TDMAT/SiH₄/N₂ gas used as a raw material gas and an argon gas used as a carrier gas was introduced into the vacuum container, and the gas within the vacuum container was discharged so as to set the partial pressure of the raw material gas at 1.0 Torr. Also, the film-forming temperature within the vacuum container was set at 330° C. In other words, the thermal CVD process was carried out under the reaction rate-determining conditions so as to form a second conductive barrier layer consisting essentially of TiSiN and having a thickness of 5 nm on the second interlayer insulating film including the via hole and the wiring trench. By this process, a conductive barrier layer 13 having a thickness of 5 to 10 nm and consisting essentially of TiSiN was formed on the second interlayer insulating film 9 including the wiring trench 11 and the via hole 10 each having the mixed layer 15 formed in the vicinity of the inner surface, the mixed layer 15 having a thickness not larger than 30 nm, as shown in FIG. 5D.

The current leakage between the adjacent wirings was measured while gradually elevating the voltage applied to the second layer wirings as in Example 1 in respect of 20 semiconductor chips obtained in Example 2. The current leakage was found to increase only moderately with increase in the voltage in respect of all of the 20 semiconductor chips as in FIG. 5 referred to previously, supporting that it was possible to suppress or prevent the current leakage between the adjacent second layer wirings.

Additional advantages and modifications will readily occur to those skilled in the art. Therefore, the present invention in its broader aspect is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a porous film formed above a semiconductor substrate, the porous film having at least one burying concave selected from the group consisting of a trench and a hole;
a conductive barrier layer formed on the inner surface of the burying concave;
a conductive member buried in the burying concave with the conductive barrier layer interposed between the porous film and the conductive member; and
a mixed layer formed between the porous film and the conductive barrier layer, and containing a component of the porous film and a component of the conductive barrier layer.

2. A semiconductor device according to claim 1, wherein the mixed layer comprises a layer constituted with the porous film, and the same component as the conductive barrier layer existing open cells of the layer constituted with the porous film.

3. A semiconductor device according to claim 1, wherein an aspect ratio D/W of the depth D to the width W of the burying concave is 1.5 or more.

4. A semiconductor device according to claim 1, wherein the conductive barrier layer is made of at least one selected from the group consisting of TiSiN, TaN, WN, WSiN and TaAlN.

5. A semiconductor device according to claim 2, wherein the concentration of the component of the conductive barrier layer contained in the mixed layer is high on the side of the conductive barrier layer and is gradually lowered with increasing distance from the conductive barrier layer, and the open cells of the porous film on the side of the conductive barrier layer are substantially closed by the same component as the conductive barrier layer.

6. A semiconductor device according to claim 1, wherein the mixed layer has a thickness not larger than 30 nm.

7. A method of manufacturing a semiconductor device, comprising:
forming at least two conductive barrier layers having substantially the same component composition by a thermal CVD method on the inner surface of at least one burying concave selected from the group consisting of a trench and a hole formed in a porous film formed above a semiconductor substrate; and
burying a conductive member in the burying concave having the conductive barrier layers formed therein;
wherein the pressure for the thermal CVD process for forming the first conductive barrier layer is set lower than the pressure for the thermal CVD process for forming the other conductive barrier layer including the second conductive barrier layer.

8. A method of manufacturing a semiconductor device according to claim 7, wherein an aspect ratio D/W of the depth D to the width W of the burying concave is 1.5 or more.

9. A method of manufacturing a semiconductor device according to claim 7, wherein the thermal CVD process for forming the first conductive barrier layer is carried out at a temperature of 300 to 370° C. and a pressure of 0.4 to 0.8 Torr, and the thermal CVD process for forming the other conductive barrier layer including the second conductive barrier layer is carried out at a temperature of 300 to 370° C. and a pressure not lower than 1.0 Torr.

10. A method of manufacturing a semiconductor device according to claim 7, wherein the thermal CVD process for forming the first conductive barrier layer is carried out so that open cells of the porous film which lies in a region extending to a distance of not larger than 30 nm from the inner surface of the burying concave is substantially closed by the same component as the conductive barrier layer.

11. A method of manufacturing a semiconductor device according to claim 7, wherein each of the thermal CVD processes is used a mixed gas, for forming a conductive barrier layer consisting essentially of TiSiN, containing at least one titanium compound gas selected from the group consisting of tetrakis(dimethylamino)titanium, tetrakis(diethylamino)titanium, and TiCl₄, at least one silicon compound gas selected from the group consisting of SiH₄ and Si₂H₆, and at least one nitrogen-containing gas selected from the group consisting of NH₃ and N₂.

12. A method of manufacturing a semiconductor device according to claim 7, wherein the conductive member is buried in the burying concave by forming a conductive film on the conductive burrier layers formed on the porous film including the burying concave and then applying a chemical mechanical polishing treatment to the conductive film.

13. A method of manufacturing a semiconductor device according to claim 7, further comprising forming an insulating protective film on the porous film, the burying concave being formed in a laminated film consisting of the porous film and the insulating protective film.

14. A method of manufacturing a semiconductor device, comprising:
forming a first conductive barrier layer by a plasma CVD process on the inner surface of at least one burying concave selected from the group consisting of a trench and a hole formed in a porous film formed above a semiconductor substrate;
forming at least one second conductive barrier layer by a thermal CVD process or an atomic layer deposition on the inner surface of the burying concave having the first conductive barrier layer formed therein; and
burying a conductive member in the burying concave having the second conductive barrier layer formed therein.

15. The method of manufacturing a semiconductor device according to claim 14, wherein an aspect ratio D/W of the depth D to the width W of the burying concave is 1.5 or more.

16. The method of manufacturing a semiconductor device according to claim 14, wherein the thermal CVD process for forming the second conductive barrier layer is carried out at a temperature of 300 to 370° C. and a pressure not lower than 1.0 Torr.

17. A method of manufacturing a semiconductor device according to claim 14, wherein the plasma CVD process for forming the first conductive barrier layer is carried out so that open cells of the porous film which lies in a region extending to a distance of not larger than 30 nm from the inner surface of the burying concave is substantially closed by the same component as the conductive barrier layer.

18. A method of manufacturing a semiconductor device according to claim 14, wherein the plasma CVD process and the thermal CVD process are used a mixed gas, for forming a conductive barrier layer consisting essentially of TiSiN, containing at least one titanium compound gas selected from the group consisting of tetrakis(dimethylamino)titanium, tetrakis(diethylamino)titanium, and TiCl₄, at least one silicon compound gas selected from the group consisting of SiH₄ and Si₂H₆, and at least one nitrogen-containing gas selected from the group consisting of NH₃ and N₂, respectively.

19. A method of manufacturing a semiconductor device according to claim 14, wherein the conductive member is buried in the burying concave by forming a conductive film on the first and second conductive burrier layers formed on the porous film including the burying concave and then applying a chemical mechanical polishing treatment to the conductive film.

20. A method of manufacturing a semiconductor device according to claim 14, further comprising forming an insulating protective film on the porous film, the burying concave being formed in a laminated film consisting of the porous film and the insulating protective film.
